(19) United States
(12) Patent Application Publication
(10) Pub. No.: US 2015/0078103 A1
(43) Pub. Date: Mar. 19, 2015

(54) SENSING TECHNIQUE FOR SINGLE-ENDED BIT LINE MEMORY ARCHITECTURES

(71) Applicant: LSI Corporation, San Jose, CA (US)

(72) Inventor: Rajiv K. Roy, Bangalore (IN)

(73) Assignee: LSI Corporation, San Jose, CA (US)

(21) Appl. No.: 14/231,680

(22) Filed: Mar. 31, 2014

(30) Foreign Application Priority Data
Sep. 13, 2013 (IN) 4131/CHE/2013

(51) Int. Cl. G11C 7/08

(52) U.S. Cl. CPC G11C 7/08
USPC 365/189.05

(57) ABSTRACT

A sense amplifier includes a latch, first and second switching circuitry, and control circuitry. The first switching circuitry selectively couples a voltage supply node and/or a voltage return node of the latch to a voltage supply and/or a voltage return of the sense amplifier, respectively, as a function of a first control signal. The second switching circuitry couples a first sensing node in the sense amplifier with a first bit line of a first sub-bank in one of multiple memory banks in a memory device as a function of a second control signal, and couples a second sensing node with a second bit line of a second sub-bank as a function of the second control signal. The control circuitry imparts an imbalance between the first and second sensing nodes which varies as a function of a third control signal.

### CROSS-REFERENCE TO RELATED APPLICATIONS

This application claims priority under 35 U.S.C. §119 from Indian Patent Application No. 4131/CHE/2013 filed in the Indian Patent Office on Sep. 13, 2013, the disclosure of which is incorporated herein by reference in its entirety.

### TECHNICAL FIELD

The present invention relates generally to electrical and electronic circuitry, and more particularly relates to semiconductor memory devices.

### BACKGROUND

A memory device is typically comprised of memory cells arranged in an array of rows and columns, with each memory cell storing one or more bits of data. Memory cells within a given row of the array are connected to a common word line, while memory cells within a given column of the array are connected to a common bit line. Each of the memory cells in the array is coupled to a unique pair of a corresponding bit line and word line for selectively accessing the memory cells.

Traditionally, in the context of single-ended bit line memory architectures, including, for example, read-only memory (ROM) and static random access memory (SRAM), the data content of a particular memory cell is read by sensing a voltage developed on a corresponding bit line coupled with the cell during a read operation. A sense amplifier is often employed to determine a logical state of the memory cell by comparing the voltage level of the corresponding bit line with a reference voltage and amplifying a difference between the bit line and reference voltages, the amplified voltage difference being indicative of the binary information (i.e., logical state) stored in the memory cell.

The reference voltage used in the comparison is often obtained from a second bit line coupled with an unselected bank of memory cells for providing a more balanced environment. In this scenario, a single-ended sense amplifier is used, with a first input of the sense amplifier being coupled with the bit line corresponding to a selected memory cell and a second input of the sense amplifier being coupled with the bit line corresponding to memory cells of an unselected bank. During the read operation, the bit line coupled with the first input of the sense amplifier will either discharge or will remain at its pre-charged level, depending on the logical state of the selected memory cell. However, this memory architecture significantly increases bit line routing complexity and increases delay, due at least in part to increased capacitance and multiplexing delay.

### SUMMARY

In accordance with an embodiment of the invention, a sense amplifier is provided for use in a memory system including a plurality of memory banks. The sense amplifier includes a latch, first and second switching circuitry, and control circuitry. The first switching circuitry selectively couples a voltage supply node and/or a voltage return node of the latch to a voltage supply and/or a voltage return of the sense amplifier, respectively, as a function of a first control signal. The second switching circuitry couples a first sensing node in the sense amplifier with a first bit line of a first sub-bank in one of multiple memory banks in a memory device as a function of a second control signal, and couples a second sensing node with a second bit line of a second sub-bank as a function of the second control signal. The control circuitry imparts an imbalance between the first and second sensing nodes which varies as a function of a third control signal. Other embodiments of the invention include but are not limited to being manifest as a sense amplifier fabricated as part of an integrated circuit, a method for improving read performance of a memory, and an electronic system. Additional and/or other embodiments of the invention are described in the following written description, including the claims, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 schematically depicts an illustrative memory device in which one or more aspects of the invention can be employed, in the context of the present disclosure;

FIG. 2 schematically depicts an exemplary unbalanced sense amplifier including multiplexing circuitry suitable for use in the illustrative memory device shown in FIG. 1, in the context of the present disclosure;

FIG. 3 is a block diagram illustrating a connection between a sense amplifier and top and bottom banks for a corresponding one of the memory banks shown in FIG. 2, in the context of the present disclosure;

FIG. 4 is a schematic diagram depicting at least a portion of an exemplary balanced sense amplifier, according to an embodiment of the invention;

FIG. 5 is a schematic diagram depicting at least a portion of an exemplary balanced sense amplifier, according to another embodiment of the invention;

FIG. 6 is a block diagram depicting at least a portion of an exemplary processing device which incorporates the illustrative memory device of FIG. 1, according to an embodiment of the invention; and

FIG. 7 is a block diagram depicting at least a portion of an exemplary processor integrated circuit incorporating the memory device of FIG. 1 as an embedded memory, according to an embodiment of the invention.

It is to be appreciated that the drawings described herein are presented for illustrative purposes only. Moreover, common but well-understood elements and/or features that may be useful or necessary in a commercially feasible embodiment may not be shown in order to facilitate a less hindered view of the illustrated embodiments.

### DETAILED DESCRIPTION

Embodiments of the invention will be described herein in the context of illustrative sense amplifier circuits for use in conjunction with a single-ended bit line memory architecture. It should be understood, however, that embodiments of the invention are not limited to these or any other particular circuit arrangements. Rather, embodiments of the invention are more broadly applicable to techniques for improving read performance in a single-ended memory system without increasing bit line routing complexity or delay, and without concern for whether the memory is embedded or standalone. In this regard, embodiments of the invention provide a sense amplifier that beneficially reduces bit line routing complexity and delay in a variety of memory arrangements and types, such as, for example, random access memory (RAM), SRAM, content addressable memory (CAM), flash memory, memory caches, register files, port buffer memories, and the like. Moreover, it will become apparent to those skilled in the art given the teachings herein that numerous modifications can be made to the illustrative embodiments shown that are within the scope of the claimed invention. That is, no limitations with respect to the embodiments shown and described herein are intended or should be inferred.

As a preliminary matter, for purposes of clarifying and describing embodiments of the invention, the following table provides a summary of certain acronyms and their corresponding definitions, as the terms are used herein:

Table of Acronym Definitions

| Acronym | Definition |
|---|---|
| ROM | Read-only memory |
| SRAM | Static random access memory |
| RAM | Random access memory |
| CAM | Content addressable memory |
| MISFET | Metal-insulator-semiconductor field-effect transistor |
| MOSFET | Metal-oxide-semiconductor field-effect transistor |
| FET | Field-effect transistor |
| NFET | N-channel field-effect transistor |
| NMOS | N-channel metal-oxide-semiconductor |
| PFET | P-channel field-effect transistor |
| PMOS | P-channel metal-oxide-semiconductor |
| CMOS | Complementary metal-oxide-semiconductor |
| BJT | Bipolar junction transistor |
| BL | Bit line |
| W/L | Width-to-length |
| MUX | Multiplexer |
| IC | Integrated circuit |
| ASIC | Application-specific integrated circuit |
| FPGA | Field-programmable gate array |
| DSP | Digital signal processor |
| CPU | Central processing unit |

Throughout the description herein, the term MISFET is intended to be construed broadly and to encompass any type of metal-insulator-semiconductor field-effect transistor. The term MISFET is, for example, intended to encompass semiconductor field-effect transistors (FETs) that utilize an oxide material as their gate dielectric (i.e., metal-oxide-semiconductor field-effect transistors (MOSFETs)), as well as those that do not. In addition, despite a reference to the term “metal” in the acronym MISFET, the term MISFET is intended to encompass semiconductor field-effect transistors wherein the gate is formed from a non-metal, such as, for instance, polysilicon.

Although embodiments of the invention described herein may be implemented using p-channel MISFETs (hereinafter called “PFETs” or “PMOS” devices) and/or n-channel MISFETs (hereinafter called “NFETs” or “NMOS” devices), as may be formed using a complementary metal-oxide-semiconductor (CMOS) fabrication process, it is to be appreciated that embodiments of the invention are not limited to such transistor devices and/or such a fabrication process, and that other suitable devices, such as, for example, bipolar junction transistors (BJTs), FinFETs, etc., and/or fabrication processes (e.g., bipolar, BiCMOS, etc.), may be similarly employed, as will be understood by those skilled in the art. Moreover, although embodiments of the invention are typically fabricated in a silicon wafer, embodiments of the invention can alternatively be fabricated in wafers comprising other materials, including but not limited to gallium arsenide (GaAs), indium phosphide (InP), etc.

Many modern memories, including, but not limited to, caches, register files, port buffer memories, CAMs, etc., utilize a single-ended bit line architecture, which eliminates a bit line from each column of memory cells, and the accompanying column decode circuitry associated therewith, thereby decreasing the semiconductor area required by the memory. As previously stated, in a single-ended bit line memory architecture, a single-ended (i.e., unbalanced) sense amplifier is often employed to determine a logical state of the memory cell by comparing the voltage level of the bit line corresponding to a selected memory cell with a reference voltage and amplifying a voltage difference between the bit line and reference voltages, the amplified voltage difference being indicative of the logical state of the memory cell.

The reference voltage used by the sense amplifier in the comparison operation is typically obtained from a second bit line coupled with an unselected bank of memory cells. In this scenario, a first input of the sense amplifier is coupled with the bit line corresponding to a bank of memory cells comprising the selected memory cell, and a second input of the sense amplifier is coupled with the bit line corresponding to the unselected bank of memory cells. During the read operation, the bit line coupled with the first input of the sense amplifier will either discharge or will remain at its pre-charged level, depending on the logical state of the selected memory cell. Since the unbalanced sense amplifier is common to both banks of memory cells, the bit lines are multiplexed, so that when a particular bank is selected, it is connected to a sensing node of the sense amplifier, and an unselected bank of memory cells is connected to a reference node of the sense amplifier. This memory arrangement, however, significantly increases bit line routing complexity and delay, due at least in part to increased capacitance and multiplexing delay.

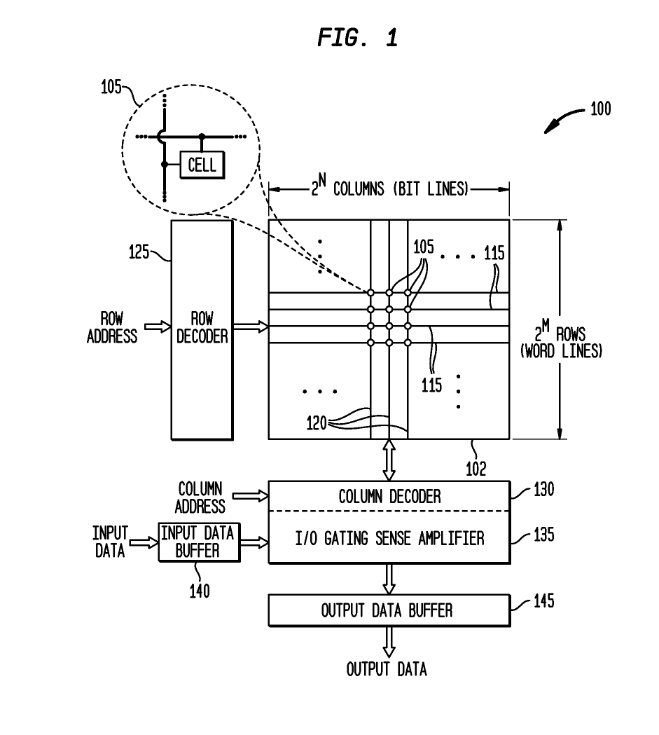

FIG. 1 schematically depicts an illustrative memory device 100 in which one or more aspects of the invention can be employed, in the context of the present disclosure. The memory device 100 includes a memory array 102 comprising a plurality of memory cells 105, each of the memory cells being configured to store data. Each memory cell 105 in a given row is coupled with a corresponding common word line 115, and each cell in a given column is coupled with a corresponding common bit line 120, such that the memory array 102 includes a memory cell 105 at each intersection of a word line 115 and a bit line 120. In this illustrative embodiment, the memory array 102 is organized having 2^{M} rows and 2^{N} columns, where M and N are integers. The values of M and N will depend upon the particular data storage requirements of the application in which the memory device 100 is used; embodiments of the invention are not limited to any specific values for M and N.

The memory cells 105 in memory device 100 can be individually accessed for writing data thereto (e.g., during a write operation) or reading data therefrom (e.g., during a read operation) by activation of appropriate row and column addresses to row decoder 125 and column decoder 130, respectively. The memory device 100 includes additional circuitry for facilitating the read and write operations, including, for example, an input/output (I/O) gating and sense amplifiers 135, input data buffers 140, and output data buffers 145.

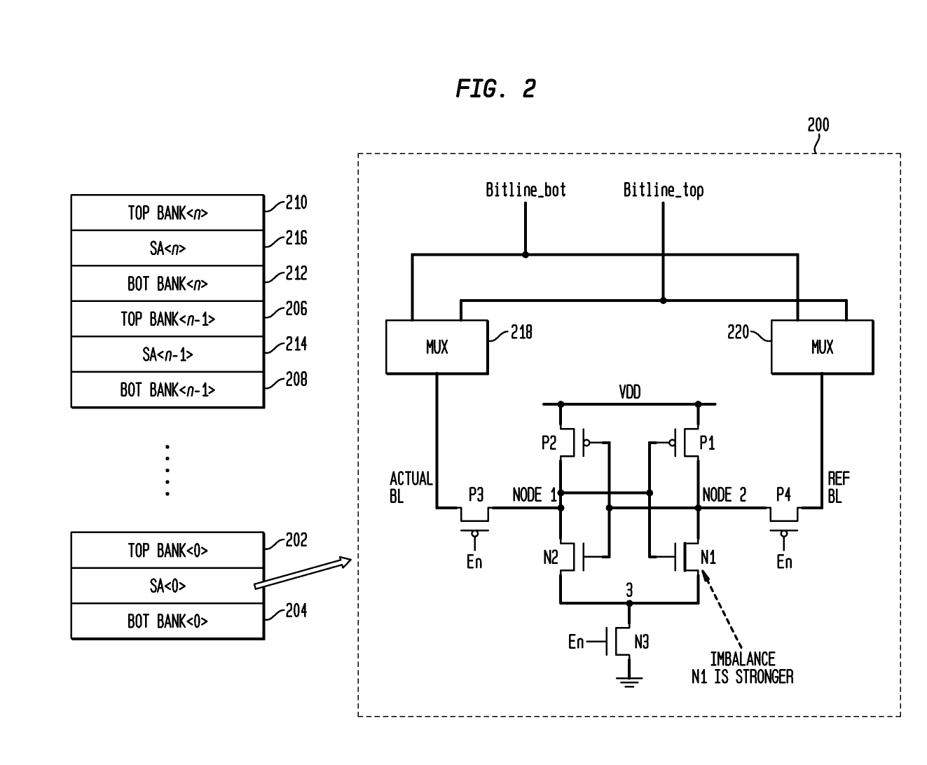

FIG. 2 schematically depicts an exemplary unbalanced sense amplifier 200 including multiplexing circuitry suitable for use in the memory device 100 shown in FIG. 1, in the context of the present disclosure. In this illustrative embodiment, at least a portion of the memory array 102 in the memory device 100 depicted in FIG. 1 is divided into a plurality of memory banks, 0 through n, where n is an integer greater than zero. Each memory bank is, in turn, divided into two sub-banks; namely, a top bank and a bottom bank. Specifically, with reference to FIG. 2, memory bank <0> comprises top bank <0> 202 and bottom bank <0> 204, memory bank <n−1> comprises top bank <n−1> 206 and bottom bank <n−1> 208, and memory bank <n> comprises top bank <n>210 and bottom bank <n>212.

The sub-banks in each memory bank share a common sense amplifier. Thus, in memory bank <0>, top bank <0> 202 and bottom bank <0> 204 share sense amplifier SA <0> 200, in memory bank <n−1>, top bank <n−1> 206 and bottom bank <−1> 208 share sense amplifier SA <n−1> 214, and in memory bank <n>, top bank <n> 210 and bottom bank <n> 212 share sense amplifier SA <n> 216. Each of the sense amplifiers in the memory device may be formed in a manner consistent with sense amplifier 200.

In this embodiment, the sense amplifier 200 is a latching sense amplifier. More particularly, sense amplifier 200 includes first and second PFETs, P3 and P4, operative as switching devices (e.g., pass gates), and a pair of cross-coupled inverters operative as a latch. A first inverter includes a PFET, P1, and an NFET, N1, and a second inverter includes a PFET, P2, and an NFET, N2. A drain of P4 is coupled with a first bit line (BL), which may be an actual bit line, a gate of P4 is adapted to receive a first (enable) control signal, En, and a source of P4 is connected with drains of P2 and N2 at node 1. Sources of P1 and P2 are connected with a voltage supply, which is VDD in this embodiment, and sources of N1 and N2 are coupled with a voltage return, which is VSS or ground in this embodiment, through an NFET, N3, operative as a switching device. A drain of N3 is connected with the sources of N1 and N2 at node 3, a source of N3 is connected with ground, and a gate of N3 is adapted to receive the control signal En. Gates of P2 and N2 are connected with drains of P1 and N1 at node 2, and gates of P1 and N1 are connected to node 1. A gate of P4 is adapted to receive the first control signal En, a drain of P4 is connected with node 2, and a source of P4 is coupled with a second bit line, which may be a reference (REF) bit line.

It is to be appreciated that, because a MISFET device is symmetrical in nature, and thus bi-directional, the assignment of source and drain designations in the MISFET device is essentially arbitrary. Therefore, the source and drain of a given MISFET device may be referred to herein generally as first and second source/drain, respectively, where “source/drain” in this context denotes a source or a drain.

In a single-ended sensing architecture, an imbalance is intentionally introduced into the sense amplifier 200 so as to make the inverters have different pull down strengths relative to one another. In this embodiment, a fixed imbalance is created between the inverters by sizing the NFET device N1 in the first inverter so that it is stronger with respect to the corresponding NFET device N2 in the second inverter. This can be achieved, for example, by increasing a channel width-to-length (W/L) ratio of N1 relative to N2. Alternatively, a W/L ratio of N2 can be decreased relative to N1, or a combination of these approaches may be used, in accordance with one or more embodiments. Making device N1 stronger than device N2 will ensure that if the respective voltages at NODE1 and NODE2 are same, NODE 2 is pulled low. This unbalanced sensing approach biases (i.e., skews) the sense amplifier 200 in one direction to thereby generate a specific output when the sensed bit line is not discharged.

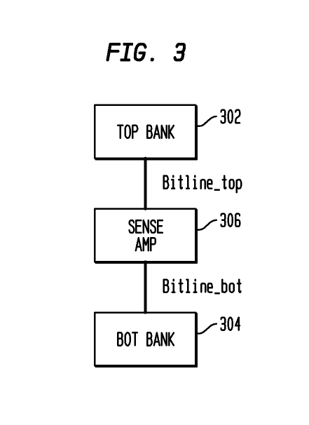

In this embodiment, the actual bit line coupled with a sensing input of the sense amplifier 200 will be a bit line associated with one of the sub-banks in a given memory bank corresponding to a selected memory cell to be read. Thus, when the selected memory cell resides in the top bank <0> 202 in memory bank <0>, the bit line serving as the actual bit line will be Bitline_top, corresponding to the top bank <0> 202, and the reference bit line will be bit line Bitline_bot, associated with the other sub-bank in which the selected memory cell does not reside; the bottom bank <0> 204 in this example. FIG. 3 illustrates this arrangement in further detail for a given one of the memory banks, wherein a top bank 302 of memory cells in the memory bank is coupled with the top bit line, Bitline_top, and a bottom bank 304 of memory cells is coupled with the bottom bit line, Bitline_bot. A corresponding sense amplifier 306, which may be implemented in a manner consistent with sense amplifier 200 shown in FIG. 2, is adapted to receive the bit lines Bitline_top and Bitline_bot corresponding to the respective top and bottom banks.

Since a selected memory cell can reside in either the top bank or the bottom bank in a selected memory bank, multiplexing circuitry coupled with the sense amplifier 200 is operative to connect the top and bottom bit lines in the selected memory bank with the appropriate actual and reference inputs of the sense amplifier. Specifically, with continued reference to FIG. 2, a first multiplexer (MUX) 218 includes a first input coupled with the bottom bit line, Bitline_bot, a second input coupled with the top bit line, Bitline_top, and an output connected with the actual bit line input of the sense amplifier 200. Likewise, a second multiplexer (MUX) 220 includes a first input coupled with the bottom bit line Bitline_bot, a second input coupled with the top bit line Bitline_top, and an output connected with the reference bit line input of the sense amplifier 200. While depicted in this illustrative embodiment as being incorporated into the sense amplifier 200, it is to be appreciated that multiplexers 218 and 220 may, alternatively, reside in switching circuitry external to the sense amplifier.

Although not explicitly shown, a second control signal, which may be a sub-bank selection or other address signal, is supplied to the first multiplexer 218, and a third control signal, which is preferably a logical complement of the second control signal, is supplied to the second multiplexer 220. Thus, when the top bit line is selected by the first multiplexer 218 as the actual bit line signal for the sense amplifier 200, the bottom bit line is selected by the second multiplexer 220 as the reference bit line signal for the sense amplifier, and vice versa. This multiplexing arrangement adds considerable routing complexity to the memory device, and moreover significantly increases capacitance of the bit lines and increases delay due, at least in part, to the multiplexing circuitry, as previously stated.

During sensing (e.g., a read operation), the sense amplifier 200 corresponding to a selected one of the memory banks is activated by asserting the control signal En, such as, for example, by setting En to a logic “low” level (e.g., zero volts). By setting En low, transistors P3 and P4 will be turned on and transistor N3 will be turned off, thereby allowing the voltage developed on the actual and reference bit lines to be applied to the internal sensing nodes 1 and 2, respectively. After a prescribed period of time, the control signal En is de-asserted, such as, for example, by setting En to a logic “high” level (e.g., VDD), thereby turning off transistors P3 and P4 and turning on transistor N3. Nodes 1 and 2 will begin to discharge to ground through transistors N1, N2 and N3. Ordinarily, if node 1 is at a lower voltage, it will discharge more rapidly because its discharge transistor (N2) will have a higher gate-to-source voltage. If, however, node 1 remains at VDD, node 2 will discharge more rapidly due to a stronger NFET N1. Once the lower voltage of nodes 1 and 2 reaches a prescribed threshold level (a PFET threshold voltage, V_{TP}), the corresponding PFET device, in this embodiment one of transistors P1 and P2, will turn on, pulling the higher voltage of nodes 1 and 2 towards the supply voltage VDD. In this manner, the initial difference in voltage between nodes 1 and 2 will be amplified. This value is retained (i.e., latched) with transistor N3 turned on. Complementary output signals are available since nodes 1 and 2 are inverses of one another after the previously described sensing operation has completed.

Rather than utilizing a fixed imbalance in the sense amplifier, which requires multiplexing circuitry (e.g., multiplexers 218 and 220) to switch which of the top and bottom bank bit lines is connected with the actual and reference bit line inputs of the sense amplifier, embodiments of the invention provide a sense amplifier architecture wherein the imbalance is not fixed, but rather changes (e.g., from one side of the sense amplifier to the other) as a function of which sub-bank in a corresponding memory bank is selected. For example, if the top bank contains the selected memory cell, the portion of the sense amplifier coupled with the bottom bank is made stronger relative to the other portion of the sense amplifier, and vice versa. Thus, a sense amplifier in accordance with one or more embodiments of the invention is automatically skewed in a direction favoring the unselected bank, without the need for multiplexing circuitry in a critical path of the read operation, and other disadvantages associated therewith. The term “skewed” as used herein is intended to broadly refer to a lowering of the switching threshold of one portion of the sense amplifier relative to another portion of the sense amplifier.

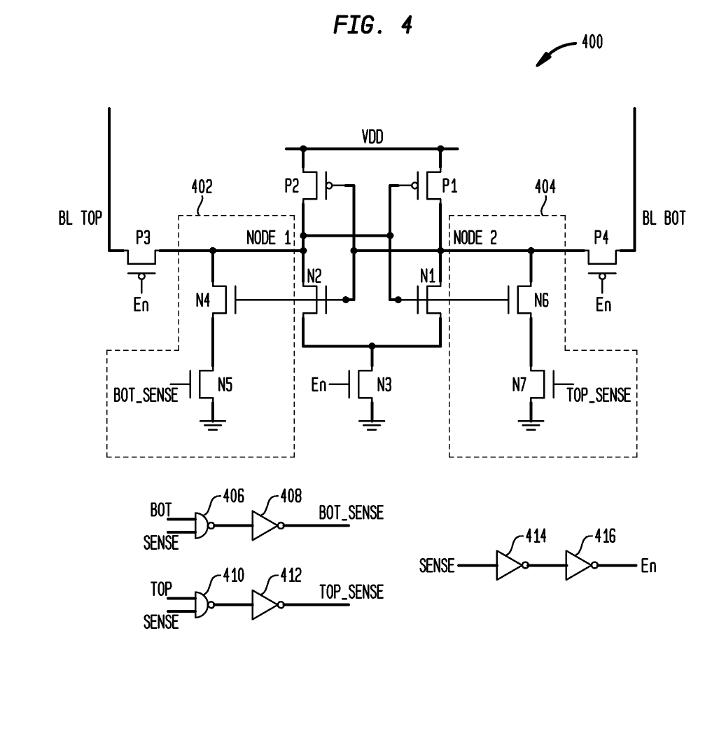

FIG. 4 is a schematic diagram depicting at least a portion of an exemplary balanced sense amplifier 400, according to an embodiment of the invention. The sense amplifier 400, in this embodiment, is implemented in a manner similar to the illustrative sense amplifier 200 shown in FIG. 2, with an exception that the first inverter, comprising PFET P1 and NFET N1, is substantially matched with the second inverter, comprising PFET P2 and NFET N2; in other words, there is no fixed imbalance introduced by skewing a switching threshold of one of the inverters relative to the other inverter. Instead, the sense amplifier 400 is a balanced differential sense amplifier which includes control circuitry operative to apply an imbalance to the internal sensing nodes that changes as a function of which memory sub-bank is selected (e.g., top bank or bottom bank).

More particularly, the sense amplifier 400 comprises control circuitry including a first control circuit 402 coupled with the first internal sensing node, node 1, of the sense amplifier, and a second control circuit 404 coupled with the second internal sensing node, node 2, of the sense amplifier. Node 1, which in this embodiment is an actual sensing node, is coupled with the top bank bit line, BL TOP, in a corresponding memory bank through PFET P3 as a function of a first control signal, which in this embodiment is a sense enable signal, En. Likewise, node 2, which in this embodiment is a reference sensing node, is coupled with the bottom bank bit line, BL BOT, in the corresponding memory bank through PFET P4 as a function of the sense enable signal En. Thus, in comparison to the sense amplifier 200 shown in FIG. 2, sense amplifier 400 advantageously eliminates the multiplexers 218 and 220, which otherwise add significant delay to the read path.

The first control circuit 402 includes a pair of NFET devices, N4 and N5, connected in series between the first internal sensing node 1 and ground. Specifically, a drain of N4 is connected with node 1, a source of N4 is connected with a drain of N5, a source of N5 is connected with a voltage return of the sense amplifier 400, which in this embodiment is ground, a gate of N5 is adapted to receive a second control signal, BOT_SENSE, and a gate of N4 is connected with the opposite internal sensing node 2. Likewise, the second control circuit 404 includes a pair of NFET devices, N6 and N7, connected in series between the second internal sensing node 2 and ground. Specifically, a drain of N6 is connected with node 2, a source of N6 is connected with a drain of N7, a source of N7 is connected with ground, a gate of N7 is adapted to receive a third control signal, TOP_SENSE, and a gate of N6 is connected with the opposite internal sensing node 1.

The sense enable signal En is indicative of a sense signal, SENSE, supplied to the sense amplifier 400. In this embodiment, the sense enable signal En is essentially a buffered version of the sense signal, generated by passing the sense signal through a pair of series-connected inverters, 414 and 416. The second control signal BOT_SENSE is generated as a function of the sense signal and a bottom bank select signal, BOT. The second control signal BOT_SENSE, in this embodiment, is generated by passing the sense signal (SENSE) and the bottom bank selection signal (BOT) through a first NAND gate 406, and then inverting the output of the first NAND gate using an inverter 408, or via alternative means. Thus, the BOT_SENSE control signal is a logical AND of the sense signal and the bottom bank selection signal. The third control signal TOP_SENSE, in this embodiment, is generated by passing the sense signal (SENSE) and the top bank selection signal (TOP) through a second NAND gate 410, and then inverting the output of the second AND gate using an inverter 412, or via alternative means. Thus, the TOP_SENSE signal is a logical AND of the sense signal and the top bank selection signal.

Preferably, the delay in the arrival of the sense enable signal En and the BOT_SENSE or TOP_SENSE control signals are substantially matched. This can be achieved, in one or more embodiments, by adjusting a delay in the output path of the circuitry used to generate the En, BOT_SENSE and TOP_SENSE control signals, or, in one or more other embodiments, by modifying the number of inverters used in generating the En, BOT_SENSE and TOP_SENSE control signals, as will become apparent to those skilled in the art given the teachings herein.

In terms of operation, when the bottom bank is selected, the bottom bank selection signal BOT will be set to a logic “1” level (e.g., VDD), and when the sense enable signal SENSE arrives, the BOT_SENSE control signal and the enable signal En will both be asserted high (e.g., VDD). The top bank selection signal will be set to a logic “0” level (e.g., ground or zero), and therefore the TOP_SENSE control signal will be de-asserted low (e.g., ground or zero). With BOT_SENSE at a high level, the first control circuit 402 connected with node 1 will be enabled by turning on NFET N5. Likewise, with TOP_SENSE at a low level, the second control circuit 404 connected with node 2 will be disabled by turning off NFET N7. With the enable signal En high, NFET N3 will be turned on, providing a current discharge path to ground. If the bottom bank bit line BL BOT did not discharge, as in the case of a read “1” operation, node 2 will be at a high level, thereby turning on NFET N4. Node 1 will therefore discharge at a faster rate compared to node 2 due to the stronger discharge path to ground through devices N4 and N5. Alternatively, if the bottom bank bit line BL BOT sufficiently discharges, as in the case of a read “0” operation, node 2 will discharge at a faster rate compared to node 1 even though it has a weaker discharge path to ground. This is because NFET N4 will be turned off once node 2 discharges to below an NMOS threshold voltage (V_{TN}) above ground, thereby disabling the node 1 discharge path.

Similarly, when the top bank is selected, the top bank selection signal TOP will be set to a logic “1” level (e.g., VDD), and when the sense enable signal SENSE arrives, the TOP_SENSE control signal and the enable signal En will both be asserted high (e.g., VDD). The bottom bank selection signal will be set to a logic “0” level (e.g., ground or zero), and therefore the BOT_SENSE control signal will be de-asserted low (e.g., ground or zero). With TOP_SENSE at a high level, the second control circuit 404 connected with node 2 will be enabled by turning on NFET N7. Likewise, with BOT_SENSE at a low level, the first control circuit 402 connected with node 1 will be disabled by turning off NFET N5. With the enable signal En high, NFET N3 will be turned on, providing a current discharge path to ground. If the top bank bit line BL TOP did not discharge, as in the case of a read “1” operation, node 1 will be at a high level, thereby turning on NFET N6. Node 2 will therefore discharge at a faster rate compared to node 1 due to the stronger discharge path to ground through devices N6 and N7. Alternatively, if the top bank bit line BL TOP sufficiently discharges, as in the case of a read “0” operation, node 1 will discharge at a faster rate compared to node 2 even though it has a weaker discharge path to ground. This is because NFET N6 will be turned off once node 1 discharges to below an NMOS threshold voltage above ground, thereby disabling the node 2 discharge path.

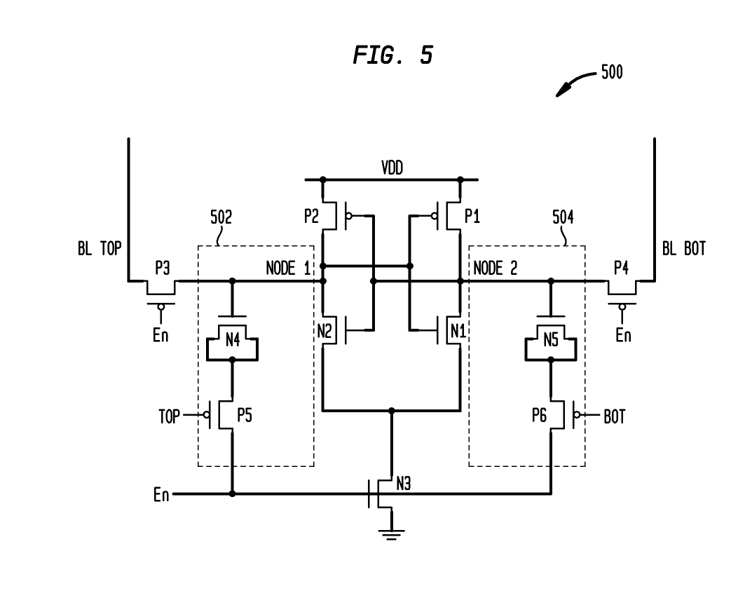

FIG. 5 is a schematic diagram depicting at least a portion of an exemplary balanced sense amplifier 500, according to another embodiment of the invention. The sense amplifier 500 is implemented in a manner similar to the illustrative sense amplifier 400 shown in FIG. 4, with an exception that the control circuitry operative to apply a selective imbalance to the internal sensing nodes (nodes 1 and 2) of the sense amplifier 500 has been modified in accordance with another embodiment of the invention.

With reference to FIG. 5, the sense amplifier 500 includes a first control circuit 502 connected with internal sensing node 1, and a second control circuit 504 connected with internal sensing node 2. Each of the control circuits 502, 504 includes a capacitive element connected in series with a switch between a corresponding internal sensing node and the sense enable signal En connection. Thus, the control circuitry 502, 504 allows capacitive coupling to be introduced onto the internal sensing nodes of the sense amplifier 500 as a function of which memory sub-bank (e.g., top bank or bottom bank) has been selected.

Specifically, the first control circuit 502 comprises a capacitive element which is implemented, in this embodiment, using an NFET device, N4, configured as a capacitor, and a switch which is implemented, in this embodiment, using a PFET device, P5. A gate of N4 is connected with internal sensing node 1, a source and drain of N4 are connected with a source of P5, a drain of P5 is adapted to receive the sense enable signal En, and a gate of P5 is adapted to receive the top bank selection signal TOP. Likewise, the second control circuit 504 comprises a capacitive element which is implemented, in this embodiment, using an NFET device, N5, configured as a capacitor, and a switch which is implemented, in this embodiment, using a PFET device, P6. A gate of N5 is connected with internal sensing node 2, a source and drain of N5 are connected with a source of P6, a drain of P6 is adapted to receive the sense enable signal En, and a gate of P6 is adapted to receive the bottom bank selection signal BOT. The control circuitry 502 and 504 employs capacitive coupling, which does not have any significant margins related to when the coupling is provided, as the coupling is provided with the arrival of sense enable signal En and no matching delays/devices are required as compared to the embodiment shown in FIG. 4.

In terms of operation, with the arrival of the sense enable signal En, an imbalance in the form of charge is applied onto the internal sensing node (e.g., node 1 or node 2) connected with the bit line corresponding to the unselected memory sub-bank. For example, when the bottom bank is selected, the bottom bank selection signal BOT will be asserted by setting the signal BOT to a logic “0” level (e.g., ground or zero) the top bank selection signal TOP will be de-asserted by setting the signal TOP to a logic “1” level (e.g., VDD). With the signal TOP at a high level, the first control circuit 502 connected with node 1 will be disabled by turning off PFET P5. Likewise, with the signal BOT at a low level, the second control circuit 504 connected with node 2 will be enabled by turning on PFET P6.

When the sense enable signal is asserted, En will go high (e.g., VDD) and with signal BOT set low, a coupling is introduced on node 2. In the case of a read “1” operation, BL BOT does not discharge, and the additional charge imparted onto node 2 by the second control circuit 504 will generate a voltage difference between the internal sensing nodes, which causes node 1 to discharge. Alternatively, in the case of a read “0” operation, BL BOT will discharge to a level such that even after receiving the additional charge imparted onto node 2 by the second control circuit 504, node 2 will still be below node 1, which is sufficient to be sensed properly by the sense amplifier 500. Thus, the achieved voltage level maintains the functionality of the sense amplifier even at low voltages.

Likewise, when the top bank is selected, the top bank selection signal TOP will be asserted by setting the signal TOP to a logic “0” level (e.g., ground or zero); the bottom bank selection signal BOT will be de-asserted by setting the signal BOT to a logic “1” level (e.g., VDD). With the signal BOT at a high level, the second control circuit 504 connected with node 2 will be disabled by turning off PFET P6. Likewise, with the signal TOP at a low level, the first control circuit 502 connected with node 1 will be enabled by turning on PFET P5.

When the sense enable signal is asserted, En will go high (e.g., VDD) and with signal TOP set low, a coupling is introduced on node 1. In the case of a read “1” operation, BL TOP does not discharge, and the additional charge imparted onto node 1 by the first control circuit 502 will generate a voltage difference between the internal sensing nodes which causes node 2 to discharge. Alternatively, in the case of a read “0” operation, BL TOP will discharge to a level such that even after receiving the additional charge imparted onto node 1 by the first control circuit 502, node 1 will still be below node 2, which is sufficient to be sensed properly by the sense amplifier 500.

It should be understood that the use of PMOS and NMOS transistor devices in the particular memory cell embodiments shown in the figures and described herein above are by way of illustration only. In other embodiments, the conductivity type of each of certain transistor devices in the memory cell may be substituted with a transistor device having a reverse conductivity type. For example, a PMOS device may be replaced by an NMOS device, with a logical complement of a control signal supplied to the PMOS device being supplied to the NMOS device, as will become apparent to those skilled in the art.

A given memory cell and/or memory device configured in accordance with one or more embodiments of the invention may be implemented as a standalone memory device, for example, as a packaged integrated circuit (IC) memory device suitable for incorporation into a higher-level circuit board or other system. Alternatively, one or more embodiments of the invention may be implemented as an embedded memory device, where the memory may be, for example, embedded into a processor or other type of integrated circuit device which comprises additional circuitry coupled with the memory device. More particularly, a memory device as described herein may comprise an embedded memory implemented within a microprocessor, digital signal processor (DSP), application-specific integrated circuit (ASIC), field-programmable gate array (FPGA), or other type of processor or integrated circuit device.

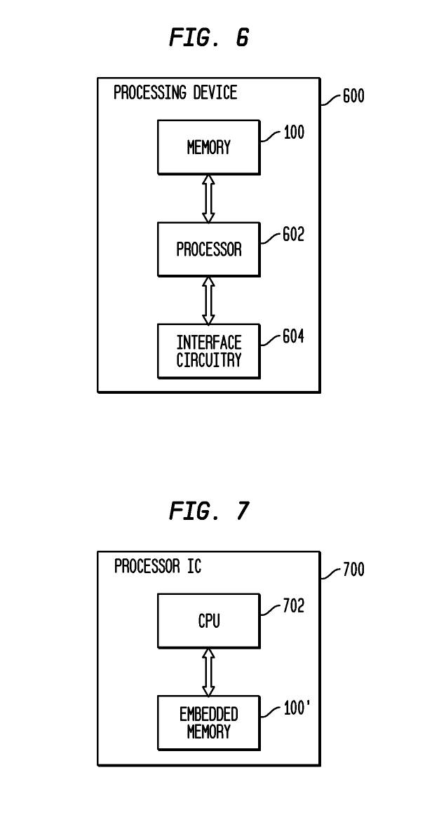

FIG. 6 is a block diagram depicting at least a portion of an exemplary processing device 600 which incorporates the illustrative memory device 100 of FIG. 1, according to an embodiment of the invention. In this embodiment, the memory device 100, which comprises one or more memory cells configured in accordance with one or more embodiments of the invention, is coupled with a processor 602. The processing device 600 further includes interface circuitry 604 coupled with the processor 602. The processing device 600 may comprise, for example, a computer, a server, a communication device, including, but not limited to, a mobile phone or tablet device, etc. The interface circuitry 604 may comprise one or more transceivers for allowing the processing device 600 to communicate over a network or other communication channel.

Alternatively, processing device 600 may comprise a microprocessor, DSP or ASIC, with processor 602 corresponding to a central processing unit (CPU) and memory device 100 providing at least a portion of an embedded memory of the microprocessor, DSP or ASIC. By way of example only and without limitation, FIG. 7 is a block diagram depicting at least a portion of an exemplary processor integrated circuit 700 incorporating the memory device of FIG. 1 as an embedded memory 100′, according to an embodiment of the invention. The embedded memory 100′ in this embodiment is coupled with a CPU 702.

In an integrated circuit implementation of one or more embodiments of the invention, multiple identical die are typically fabricated in a repeated pattern on a surface of a semiconductor wafer. Each such die may include a device described herein, and may include other structures and/or circuits. The individual dies are cut or diced from the wafer, then packaged as integrated circuits. One skilled in the art would know how to dice wafers and package die to produce integrated circuits. Any of the exemplary circuits illustrated in the accompanying figures, or portions thereof, may be part of an integrated circuit. Integrated circuits so manufactured are considered part of this invention.

The illustrations of embodiments of the invention described herein are intended to provide a general understanding of the structure of various embodiments, and they are not intended to serve as a complete description of all the elements and features of apparatus and systems that might make use of the structures described herein. Many other embodiments will become apparent to those skilled in the art given the teachings herein; other embodiments are utilized and derived therefrom, such that structural and logical substitutions and changes can be made without departing from the scope of this disclosure. The drawings are also merely representational and are not drawn to scale. Accordingly, the specification and drawings are to be regarded in an illustrative rather than a restrictive sense.

Embodiments of the invention are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The abstract is provided to comply with 37 C.F.R. §1.72(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, inventive subject matter lies in less than all features of a single embodiment. Thus the following claims are hereby incorporated into the Detailed Description, with each claim standing on its own as separately claimed subject matter.

Given the teachings of embodiments of the invention provided herein, one of ordinary skill in the art will be able to contemplate other implementations and applications of the techniques of embodiments of the invention. Although illustrative embodiments of the invention have been described herein with reference to the accompanying drawings, it is to be understood that embodiments of the invention are not limited to those precise embodiments, and that various other changes and modifications are made therein by one skilled in the art without departing from the scope of the appended claims.

What is claimed is:

1. A sense amplifier for use in a memory system comprising a plurality of memory banks, the sense amplifier comprising:
a latch coupled with first and second sensing nodes of the sense amplifier, the latch being operative to store a state of the sense amplifier;
first switching circuitry operative to selectively couple a least one of a voltage supply node and a voltage return node of the latch to a voltage supply and a voltage return of the sense amplifier, respectively, as a function of a first control signal;
second switching circuitry operative to selectively couple the first sensing node with a first bit line of a first sub-bank in a corresponding one of the memory banks as a function of a second control signal, and to selectively couple the second sensing node with a second bit line of a second sub-bank in the corresponding one of the memory banks as a function of the second control signal; and
control circuitry operative to impart an imbalance between the first and second sensing nodes which varies as a function of at least a third control signal.

2. The sense amplifier of claim 1, wherein the third control signal is indicative of which of the first and second sub-banks is selected.

3. The sense amplifier of claim 1, wherein the control circuitry is operative to impart an imbalance onto the first sensing node as a function of the third control signal and operative to impart an imbalance onto the second sensing node as a function of a fourth control signal, the third control signal being indicative of a selection of the second sub-bank and the fourth control signal being indicative of a selection of the first sub-bank.

4. The sense amplifier of claim 1, wherein the control circuitry comprises:
a first control circuit coupled with the first sensing node and operative to generate a first current discharge path as a function of a selection of the second sub-bank; and
a second control circuit coupled with the second sensing node and operative to generate a second current discharge path as a function of a selection of the first sub-bank.

5. The sense amplifier of claim 4, wherein the first and second control circuits are not concurrently active.

6. The sense amplifier of claim 1, wherein the control circuitry comprises:
a first control circuit including first and second switches connected in series between the first sensing node and the voltage return node of the sense amplifier, the first switch being activated as a function of a voltage level of the second sensing node, and the second switch being activated as a function of the third control signal, the third control signal being indicative of selection of the second sub-bank; and
a second control circuit including third and fourth switches connected in series between the second sensing node and the voltage return node of the sense amplifier, the third switch being activated as a function of a voltage level of the first sensing node, and the fourth switch being activated as a function of a fourth control signal, the fourth control signal being indicative of selection of the first sub-bank.

7. The sense amplifier of claim 6, wherein the third control signal is generated as a logical AND of a second sub-bank selection signal and a sense enable signal supplied to the sense amplifier, and the fourth control signal is generated as a logical AND of a first sub-bank selection signal and the sense enable signal supplied to the sense amplifier.

8. The sense amplifier of claim 7, wherein the first and second control signals are generated as a buffered version of the sense enable signal.

9. The sense amplifier of claim 1, wherein the control circuitry comprises:
a first control circuit including first and second NMOS devices, a first source/drain of the first NMOS device being connected with the first sensing node, a second source/drain of the first NMOS device being connected with a first source/drain of the second NMOS device, a gate of the first NMOS device being connected with the second sensing node, a second source/drain of the second NMOS device being adapted for connection with a voltage return of the sense amplifier, and a gate of the second NMOS device being adapted to receive the third control signal, the third control signal being indicative of selection of the second sub-bank; and
a second control circuit including third and fourth NMOS devices, a first source/drain of the third NMOS device being connected with the second sensing node, a second source/drain of the third NMOS device being connected with a first source/drain of the fourth NMOS device, a gate of the third NMOS device being connected with the first sensing node, a second source/drain of the fourth NMOS device being adapted for connection with the voltage return of the sense amplifier, and a gate of the fourth NMOS device being adapted to receive a fourth control signal, the fourth control signal being indicative of selection of the first sub-bank.

10. The sense amplifier of claim 1, wherein the control circuitry comprises:
a first control circuit including a first capacitive element and a first switch, a first terminal of the first capacitive element being connected with the first sensing node, a second terminal of the capacitive element being connected with the first switch, the first switch being operative to couple the first capacitive element with the first control signal as a function of the third control signal, the third control signal being indicative of selection of the first sub-bank; and
a second control circuit including a second capacitive element and a second switch, a first terminal of the second capacitive element being connected with the second sensing node, a second terminal of the capacitive element being connected with the second switch, the second switch being operative to couple the second capacitive element with the first control signal as a function of a fourth control signal, the fourth control signal being indicative of selection of the second sub-bank.

11. The sense amplifier of claim 10, wherein the first and second control signals comprise a sense enable signal, the third control signal comprises a first sub-bank selection signal, and the fourth control signal comprises a second sub-bank selection signal supplied to the sense amplifier.

12. The sense amplifier of claim 1, wherein the latch comprises first and second cross-coupled inverters, an output of the second inverter forming the first sensing node of the sense amplifier and an output of the first inverter forming the second sensing node of the sense amplifier.

13. The sense amplifier of claim 1, wherein the first switching circuitry comprises at least one MOS device, a first source/drain of the MOS device being connected with one of the voltage return node and the voltage supply node of the latch, a second source/drain of the MOS device being connected with one of the voltage return and the voltage supply of the sense amplifier, respectively, and a gate of the MOS device being adapted to receive the first control signal.

14. The sense amplifier of claim 1, wherein the second switching circuitry comprises first and second MOS devices, a first source/drain of the first MOS device being adapted for connection with the first bit line of the first sub-bank, a second source/drain of the first MOS device being connected with the first sensing node, a first source/drain of the second MOS device being adapted for connection with the second bit line of a second sub-bank, a second source/drain of the second MOS device being connected with the second sensing node, and gates of the first and second MOS devices being adapted to receive the second control signal.

15. The sense amplifier of claim 1, wherein one of the first and second bit lines is coupled with an unselected memory sub-bank during a sensing operation and is operative as a reference bit line, whereby a reference voltage conveyed by the reference bit line is used by the sense amplifier in a comparison operation with a voltage conveyed by another of the first and second bit lines coupled with a selected memory sub-bank.

16. The sense amplifier of claim 1, wherein at least a portion of the sense amplifier is fabricated in at least one integrated circuit.

17. A method for improving read performance in a single-ended memory system comprising a plurality of memory banks, the method comprising:
providing a sense amplifier including a latch coupled with first and second sensing nodes of the sense amplifier;
connecting a least one of a voltage supply node and a voltage return node of the latch to a voltage supply and a voltage return of the sense amplifier, respectively, as a function of a first control signal;
connecting the first sensing node with a first bit line of a first sub-bank in a corresponding one of the memory banks as a function of a second control signal, and connecting the second sensing node with a second bit line of a second sub-bank in the corresponding one of the memory banks as a function of the second control signal; and
imparting an imbalance between the first and second sensing nodes which varies as a function of at least a third control signal.

18. The method of claim 17, wherein imparting an imbalance between the first and second sensing nodes comprises:
providing a first control circuit including first and second switches connected in series between the first sensing node and the voltage return node of the sense amplifier, the first switch being activated as a function of a voltage level of the second sensing node, and the second switch being activated as a function of the third control signal, the third control signal being indicative of selection of the second sub-bank; and
providing a second control circuit including third and fourth switches connected in series between the second sensing node and the voltage return node of the sense amplifier, the third switch being activated as a function of a voltage level of the first sensing node, and the fourth switch being activated as a function of a fourth control signal, the fourth control signal being indicative of selection of the first sub-bank.

19. The method of claim 18, further comprising:
generating the third control signal as a logical AND of a second sub-bank selection signal and a sense enable signal supplied to the sense amplifier; and
generating the fourth control signal as a logical AND of a first sub-bank selection signal and the sense enable signal supplied to the sense amplifier.

20. The method of claim 17, wherein imparting an imbalance between the first and second sensing nodes comprises:
creating a first current discharge path between the first sensing node and the voltage return of the sense amplifier, the first current discharge path being controlled as a function of a voltage level of the second sensing node and the third control signal, the third control signal being indicative of selection of the second sub-bank; and
creating a second current discharge path between the second sensing node and the voltage return of the sense amplifier, the second current discharge path being controlled as a function of a voltage level of the first sensing node and a fourth control signal, the fourth control signal being indicative of selection of the first sub-bank.

21. The method of claim 17, wherein imparting an imbalance between the first and second sensing nodes comprises:
providing a first control circuit including a first capacitive element and a first switch connected together in series between the first sensing node and the first control signal, the first control circuit imparting a charge on the first sensing node as a function of the third control signal, the third control signal being indicative of selection of the first sub-bank; and
providing a second control circuit including a second capacitive element and a second switch connected together in series between the second sensing node and the first control signal, the second control circuit imparting a charge on the second sensing node as a function of a fourth control signal, the fourth control signal being indicative of selection of the second sub-bank.

22. An electronic system, comprising:
at least one memory comprising a plurality of memory banks; and
at least one sense amplifier coupled with the memory, the at least one sense amplifier comprising:
a latch coupled with first and second sensing nodes of the sense amplifier, the latch being operative to store a state of the sense amplifier;
first switching circuitry operative to selectively couple a least one of a voltage supply node and a voltage return node of the latch to a voltage supply and a voltage return of the sense amplifier, respectively, as a function of a first control signal;
second switching circuitry operative to selectively couple the first sensing node with a first bit line of a first sub-bank in a corresponding one of the memory banks as a function of a second control signal, and to selectively couple the second sensing node with a second bit line of a second sub-bank in the corresponding one of the memory banks as a function of the second control signal; and
control circuitry operative to impart an imbalance between the first and second sensing nodes which varies as a function of at least a third control signal.
